(19) United States
(12) Patent Application Publication
(10) Pub. No.: US 2026/0118756 A1
(43) Pub. Date: Apr. 30, 2026

(54) SEMICONDUCTOR PHOTORESIST COMPOSITION AND METHOD OF FORMING PATTERNS USING THE COMPOSITION

(71) Applicant: SAMSUNG SDI CO., LTD., Yongin-si (KR)

(72) Inventors: Sumin JANG, Suwon-si (KR); Soobin LIM, Suwon-si (KR); Yunju CHAE, Suwon-si (KR); Hyun LEE, Suwon-si (KR); Joonhee HAN, Suwon-si (KR)

(21) Appl. No.: 19/376,402

(22) Filed: Oct. 31, 2025

(30) Foreign Application Priority Data
Oct. 31, 2024 (KR) 10-2024-0152907

(51) Int. Cl. G03F 7/004; G03F 7/00

(52) U.S. Cl. CPC G03F 7/0042; G03F 7/70033

(57) ABSTRACT

A semiconductor photoresist composition and a method of forming patterns using the semiconductor photoresist composition are provided. The semiconductor photoresist composition includes an organometallic compound represented by Chemical Formula 1 and a solvent. The organometallic compound includes tin and at least one amido ligand containing a substituted or unsubstituted alkenyl moiety or alkynyl moiety.

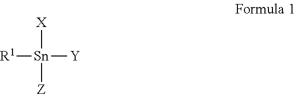

### CROSS-REFERENCE TO RELATED APPLICATION

The present application claims priority to and the benefit of Korean Patent Application No. 10-2024-0152907, filed on Oct. 31, 2024, in the Korean Intellectual Property Office, the entire content of which is incorporated herein by reference.

### BACKGROUND

### 1. Field

One or more embodiments of the present disclosure relate to a semiconductor photoresist composition and a method of forming patterns using the same.

### 2. Description of the Related Art

Extreme ultraviolet (EUV) lithography has emerged as an important technology for manufacturing next-generation semiconductor devices, such as advanced semiconductor chips (e.g., next generation semiconductor chips). EUV lithography utilizes EUV radiation with a wavelength of 13.5 nm as an exposure light source, enabling the formation of extremely fine patterns, for example, patterns having critical dimensions of 20 nm or less.

Achieving high-resolution patterning with EUV lithography requires the development of compatible photoresists capable of sub-16 nm resolution. However, chemically amplified (CA) photoresists currently face limitations in resolution, photospeed, and line edge roughness (LER), which hinder their performance in advanced lithographic processes.

In CA photoresists, acid-catalyzed reactions may cause image blurring, particularly at small feature sizes, a limitation also observed in electron beam lithography. Although CA photoresists are designed for high sensitivity, their typical elemental composition results in low absorbance at 13.5 nm, thereby reducing sensitivity under EUV exposure.

Additionally, CA photoresists may often exhibit increased LER as photospeed decreases, due in part to the stochastic nature of acid diffusion and reaction. These limitations underscore the need for novel, high-performance photoresist materials suitable for EUV lithography.

In response, research has turned to inorganic photoresist compositions, which are primarily used for negative tone patterning. These compositions undergo chemical modification through non-chemically amplified mechanisms, providing resistance to developer solutions. Inorganic photoresists typically contain elements with higher EUV absorption than hydrocarbons, offering improved sensitivity, reduced stochastic effects, and lower LER.

Inorganic photoresists based on peroxopolyacids of tungsten, optionally mixed with elements such as niobium, titanium, and/or tantalum, have been explored as radiation-sensitive materials for patterning.

These materials have demonstrated efficacy in patterning large-pitch features using bilayer configurations and various radiation sources, including deep UV, X-ray, and electron beam. For example, cationic hafnium metal oxide sulfate (HfSOx) materials, when combined with a peroxo complexing agent, have enabled imaging of 15 nm half-pitch features via EUV projection exposure. While this system offers high performance and acceptable photospeed, it suffers from practical drawbacks: (i) the coating process involves corrosive sulfuric acid/hydrogen peroxide mixtures, leading to poor shelf-life stability; (ii) structural modifications for performance enhancement are difficult; and (iii) development requires highly concentrated tetramethylammonium hydroxide (TMAH) solutions (e.g., 25 wt %).

To address these issues and challenges, recent efforts have focused on tin-containing molecules with strong EUV absorption. Among these, organotin polymers have shown promise. Upon EUV exposure, alkyl ligands dissociate and form oxo bonds with adjacent chains, enabling negative tone patterning resistant to organic developers. Although these organotin polymers exhibit improved sensitivity, resolution, and LER, further enhancements are needed to meet commercial performance requirements.

### SUMMARY

One or more aspects of embodiments of the present disclosure are directed toward a semiconductor photoresist composition that is capable of implementing a photoresist pattern with excellent or suitable sensitivity and LER characteristics, and suppressing bridge defects.

One or more aspects of embodiments of the present disclosure are directed toward a method of forming patterns using the semiconductor photoresist composition.

Additional aspects will be set forth in part in the description which follows and, in part, will be apparent from the description, or may be learned by practice of the presented embodiments of the disclosure.

According to one or more embodiments of the present disclosure, a semiconductor photoresist composition includes an organometallic compound represented by Chemical Formula 1 and a solvent.

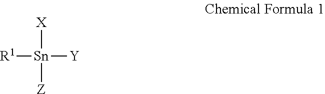

In Chemical Formula 1,
R¹ may be selected from among a substituted or unsubstituted C1 to C20 alkyl group, a substituted or unsubstituted C2 to C30 heteroalkyl group, a substituted or unsubstituted C3 to C20 cycloalkyl group, a substituted or unsubstituted C2 to C30 heterocycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C2 to C30 heteroaryl group, a substituted or unsubstituted C7 to C30 arylalkyl group, a substituted or unsubstituted C4 to C30 heteroarylalkyl group, and a substituted or unsubstituted C1 to C30 alkylcarbonyl group,
X, Y, and Z may each independently be a substituted or unsubstituted C1 to C20 alkyl group, a substituted or unsubstituted C2 to C30 heteroalkyl group, a substituted or unsubstituted C3 to C20 cycloalkyl group, a substituted or unsubstituted C2 to C30 heterocycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C2 to C30 heteroaryl group, a substituted or unsubstituted C7 to C30 arylalkyl group, a substituted or unsubstituted C4 to C30 heteroarylalkyl group, a substituted or unsubstituted C1 to C30 alkylcarbonyl group, or —N(L^{a}-R^{a})(L^{b}-R^{b}),
at least one selected from among X, Y, and Z is —N(L^{a}-R^{a})(L^{b}-R^{b}),
L^{a} and L^{b} may each independently be a single bond or a substituted or unsubstituted C1 to C10 alkylene group, and
R^{a} and R^{b} may each independently be a substituted or unsubstituted C2 to C20 alkenyl group or a substituted or unsubstituted C2 to C20 alkynyl group.

According to one or more embodiments of the present disclosure, a method of forming patterns includes forming an etching-objective layer (e.g., etching-target layer) on a substrate, coating the semiconductor photoresist composition on the etching-objective layer to form a photoresist film, exposing and developing the photoresist film to form a photoresist film having a photoresist pattern formed thereon, and etching the etching-objective layer using the photoresist pattern as an etching mask.

The semiconductor photoresist composition according to one or more embodiments of the present disclosure may provide a photoresist pattern having enhanced (e.g., improved) sensitivity and LER characteristics and enhanced (e.g., suppressed or reduced) bridge defects. These enhancements are, for example, beneficial in advanced semiconductor manufacturing processes where pattern fidelity and defect control are important for device performance and yield.

Without being bound by theory, it is believed that the organometallic compound represented by Chemical Formula 1 contributes to enhanced EUV absorption and controlled crosslinking behavior during exposure. This results in a more uniform and stable photoresist pattern, even at sub-20 nm critical dimensions. Furthermore, the inclusion of specific ligand structures in the organometallic framework may facilitate improved solubility and film-forming properties, thereby enhancing process compatibility with conventional spin-coating and development techniques. These features collectively support the practical application of the disclosed photoresist composition in high-resolution lithographic processes for next-generation semiconductor devices.

### BRIEF DESCRIPTION OF DRAWINGS

The accompanying drawings are included to provide a further understanding of the present disclosure and are incorporated in and constitute a part of the present disclosure. The drawings illustrate embodiments of the present disclosure and, together with the description, serve to explain principles of the present disclosure. The above and other aspects, features, and advantages of certain embodiments of the disclosure will be more apparent from the following description taken in conjunction with the accompanying drawings, in which:

FIGS. 1A-1E are cross-sectional views for illustrating a method of forming patterns using a semiconductor photoresist composition according to one or more embodiments of the present disclosure.

### DETAILED DESCRIPTION

The present disclosure may be modified in many alternate forms, and thus specific embodiments will be exemplified in the drawing and described in more detail. It should be understood, however, that it is not intended to limit the present disclosure to the particular forms disclosed, but rather, is intended to cover all modifications, equivalents, and alternatives falling within the spirit and scope of the present disclosure.

Hereinafter, referring to the drawings, one or more embodiments of the present disclosure will be described in more detail. In the following description of the present disclosure, the well-established functions or constructions will not be described in order to make the present disclosure concise.

To clearly illustrate the present disclosure, certain unessential description and relationships are omitted, and throughout the disclosure, the same or similar configuration elements are designated by the same reference numerals. Also, because the size and thickness of each configuration shown in the drawing are shown for better understanding and ease of description, the present disclosure is not necessarily limited thereto.

In the drawings, the thickness of layers, films, panels, regions, and/or the like, may be exaggerated for clarity. In the drawings, the thickness of a part of layers or regions, and/or the like, may be exaggerated for convenience of explanation. It will be understood that if (e.g., when) an element such as a layer, film, region, or substrate is referred to as being “on” another element, it may be directly on the other element or one or more intervening elements may also be present therebetween. In contrast, when an element is referred to as being “directly on” another element, there are no intervening elements present.

As used herein, “substituted” refers to replacement of a hydrogen by deuterium, a halogen, a hydroxyl group, a carboxyl group, a thiol group, a cyano group, a nitro group, —NRR′ (wherein, R and R′ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), —SiRR′R″ (wherein, R, R′, and R″ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, a C1 to C20 sulfide group, or a combination thereof. “Unsubstituted” refers to non-replacement of a hydrogen by another substituent and remaining of the hydrogen.

As used herein, if (e.g., when) a definition is not otherwise provided, the term “alkyl group” refers to a linear or branched aliphatic hydrocarbon group. The alkyl group may be a “saturated alkyl group” without any double bond or triple bond.

The alkyl group may be a C1 to C8 alkyl group. For example, the alkyl group may be a C1 to C7 alkyl group, a C1 to C6 alkyl group, or a C1 to C5 alkyl group. For example, the C1 to C5 alkyl group may be a methyl group, an ethyl group, a propyl group, an isopropyl group, an n-butyl group, an isobutyl group, a sec-butyl group, a tert-butyl group, or a 2,2-dimethylpropyl group.

As used herein, if (e.g., when) a definition is not otherwise provided, the term “cycloalkyl group” refers to a monovalent cyclic aliphatic hydrocarbon group.

The cycloalkyl group may be a C3 to C8 cycloalkyl group, for example, a C3 to C7 cycloalkyl group, a C3 to C6 cycloalkyl group, a C3 to C5 cycloalkyl group, or a C3 to C4 cycloalkyl group. The cycloalkyl group may be a cyclopropyl group, a cyclobutyl group, a cyclopentyl group, or a cyclohexyl group, but embodiments of the present disclosure are not limited thereto.

In the present disclosure, “aliphatic unsaturated organic group” refers to a hydrocarbon group including a bond in which the bond between carbon and carbon atoms in a molecule is a double bond, a triple bond, or a combination thereof.

The aliphatic unsaturated organic group may be a C2 to C8 aliphatic unsaturated organic group. For example, the aliphatic unsaturated organic group may be a C2 to C7 aliphatic unsaturated organic group, a C2 to C6 aliphatic unsaturated organic group, C2 to C5 aliphatic unsaturated organic group, or a C2 to C4 aliphatic unsaturated organic group. For example, the C2 to C4 aliphatic unsaturated organic group may be a vinyl group, an ethynyl group, an allyl group, a 1-propenyl group, a 1-methyl-1-propenyl group, a 2-propenyl group, a 2-methyl-2-propenyl group, a 1-propynyl group, a 1-methyl-1 propynyl group, a 2-propynyl group, a 2-methyl-2-propynyl group, a 1-butenyl group, a 2-butenyl group, a 3-butenyl group, a 1-butynyl group, a 2-butynyl group, or a 3-butynyl group.

As used herein, the term “aryl group” refers to a substituent in which all atoms in the cyclic substituent have a p-orbital and these p-orbitals are conjugated and may include a monocyclic or fused ring polycyclic functional group (i.e., rings sharing adjacent pairs of carbon atoms).

As used herein, the term “heteroaryl group” may refer to an aryl group including at least one heteroatom selected from among N, O, S, P, and Si. Two or more heteroaryl groups may be linked by a sigma bond directly, or if (e.g., when) the heteroaryl group includes two or more rings, the two or more rings may be fused. When the heteroaryl group is a fused ring, one or more rings thereof may include one to three heteroatoms.

As used herein, unless otherwise defined, the term “alkenyl group” refers to a linear or branched aliphatic hydrocarbon group including at least one double bond as an aliphatic unsaturated alkenyl group.

As used herein, unless otherwise defined, “alkynyl group” refers to a linear or branched aliphatic hydrocarbon group including at least one triple bond as an aliphatic unsaturated alkynyl group.

Hereinafter, a semiconductor photoresist composition according to one or more embodiments will be described.

A semiconductor photoresist composition according to one or more embodiments may include an organometallic compound represented by Chemical Formula 1 and a solvent.

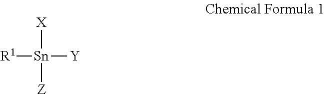

In Chemical Formula 1,
R¹ may be selected from among a substituted or unsubstituted C1 to C20 alkyl group, a substituted or unsubstituted C2 to C30 heteroalkyl group, a substituted or unsubstituted C3 to C20 cycloalkyl group, a substituted or unsubstituted C2 to C30 heterocycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C2 to C30 heteroaryl group, a substituted or unsubstituted C7 to C30 arylalkyl group, a substituted or unsubstituted C4 to C30 heteroarylalkyl group, and a substituted or unsubstituted C1 to C30 alkylcarbonyl group,
X, Y, and Z may each independently be a substituted or unsubstituted C1 to C20 alkyl group, a substituted or unsubstituted C2 to C30 heteroalkyl group, a substituted or unsubstituted C3 to C20 cycloalkyl group, a substituted or unsubstituted C2 to C30 heterocycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C2 to C30 heteroaryl group, a substituted or unsubstituted C7 to C30 arylalkyl group, a substituted or unsubstituted C4 to C30 heteroarylalkyl group, a substituted or unsubstituted C1 to C30 alkylcarbonyl group, or —N(L^{a}-R^{a})(L^{b}-R^{b}),
at least one selected from among X, Y, and Z is —N(L^{a}-R^{a})(L^{b}-R^{b}),
L^{a} and L^{b} may each independently be a single bond or a substituted or unsubstituted C1 to C10 alkylene group, and
R^{a} and R^{b} may each independently be a substituted or unsubstituted C2 to C20 alkenyl group, a substituted or unsubstituted C2 to C20 alkynyl group.

The organometallic compound according to the present disclosure can further improve sensitivity and LER characteristics by including an unsaturated bond in a hydrolyzable amido group/ligand, thereby enabling crosslinking between ligands and helping in the formation of metal clusters.

For example, in one or more embodiments, the unsaturated bond may be present inside the amido group/ligand (e.g., in the middle of a carbon chain of the amido group/ligand) rather than at the terminal end thereof.

For example, L^{a} and L^{b} may each independently be a single bond or a substituted or unsubstituted C1 to C10 alkylene group,

In one or more embodiments, R^{a} and R^{b} may each independently be —C(R²)═C(R³)(R⁴) or —C≡C(R⁵),
R² to R⁴ may each independently be hydrogen, a substituted or unsubstituted C1 to C20 alkyl group, a substituted or unsubstituted C3 to C20 cycloalkyl group, a substituted or unsubstituted C6 to C30 aryl group, -L¹-C(R⁶)═C(R⁷)(R⁸), or -L²-C≡C(R⁹),
at least one of R³ or R⁴ may be a substituted or unsubstituted C1 to C20 alkyl group, a substituted or unsubstituted C3 to C20 cycloalkyl group, a substituted or unsubstituted C6 to C30 aryl group, -L¹-C(R⁶)═C(R⁷)(R⁸), or -L²-C≡C(R⁹),
R⁵ may be a substituted or unsubstituted C1 to C20 alkyl group, a substituted or unsubstituted C3 to C20 cycloalkyl group, a substituted or unsubstituted C6 to C30 aryl group, -L¹-C(R⁶)═C(R⁷)(R⁸), or -L²-C≡C(R⁹),
L¹ and L² may each independently be a substituted or unsubstituted C1 to C10 alkylene group, and
R⁶ to R⁹ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, or a substituted or unsubstituted C6 to C30 aryl group.

In this way, because the unsaturated bond is present inside the amido group/ligand (e.g., in the middle of a carbon chain of the amido group/ligand) rather than at the terminal end thereof, the reactivity may be lowered, and thus the occurrence of bridge defects after pattern formation may be suppressed or reduced.

In one or more embodiments, X, Y and Z may each independently be N(L^{a}-R^{a})(L^{b}-R^{b}).

In one or more embodiments, X, Y, and Z may be the same as one another.

In one or more embodiments, R¹ may be selected from among a substituted or unsubstituted C1 to C10 alkyl group, a substituted or unsubstituted C2 to C20 heteroalkyl group, a substituted or unsubstituted C3 to C12 cycloalkyl group, a substituted or unsubstituted C2 to C20 heterocycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C2 to C20 heteroaryl group, a substituted or unsubstituted C7 to C20 arylalkyl group, a substituted or unsubstituted C4 to C20 heteroarylalkyl group, and a substituted or unsubstituted C1 to C20 alkylcarbonyl group.

In one or more embodiments, R¹ may be a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted tert-pentyl group, a substituted or unsubstituted 1-methylpropyl group, a substituted or unsubstituted 1,1-dimethylpropyl group, a substituted or unsubstituted 2,2-dimethylpropyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted phenyl group, a substituted or unsubstituted tolyl group, a substituted or unsubstituted xylene group, a substituted or unsubstituted benzyl group, or a combination thereof.

In one or more embodiments, R² to R⁴ may each independently be hydrogen, a substituted or unsubstituted C1 to C10 alkyl group, a substituted or unsubstituted C3 to C10 cycloalkyl group, a substituted or unsubstituted C6 to C20 aryl group, -L¹-C(R⁶)═C(R⁷)(R⁸), or -L²-C≡C(R⁹),
at least one of R³ or R⁴ may be a substituted or unsubstituted C1 to C10 alkyl group, a substituted or unsubstituted C3 to C10 cycloalkyl group, a substituted or unsubstituted C6 to C20 aryl group, -L¹-C(R⁶)═C(R⁷)(R⁸), or -L²-C≡C(R⁹),
R⁵ may be a substituted or unsubstituted C1 to C10 alkyl group, a substituted or unsubstituted C3 to C10 cycloalkyl group, a substituted or unsubstituted C6 to C20 aryl group, -L¹-C(R⁶)═C(R⁷)(R⁸), or -L²-C≡C(R⁹),
L¹ and L² may each independently be a substituted or unsubstituted C1 to C6 alkylene group, and
R⁶ to R⁹ may each independently be hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, or a substituted or unsubstituted C6 to C20 aryl group.

In one or more embodiments, R² to R⁴ may each independently be hydrogen, a substituted or unsubstituted C1 to C10 alkyl group, -L¹-C(R⁶)═C(R⁷)(R⁸), or -L²-C≡C(R⁹),
at least one of R³ or R⁴ may be a substituted or unsubstituted C1 to C10 alkyl group, -L¹-C(R⁶)═C(R⁷)(R⁸), or -L²-C≡C(R⁹),
R⁵ may be a substituted or unsubstituted C1 to C10 alkyl group, -L¹-C(R⁶)═C(R⁷)(R⁸), or -L²-C≡C(R⁹),
L¹ and L² may each independently be a substituted or unsubstituted C1 to C6 alkylene group, and
R⁶ to R⁹ may each independently be hydrogen, a substituted or unsubstituted C1 to C10 alkyl group, a substituted or unsubstituted C2 to C10 alkenyl group, or a substituted or unsubstituted C2 to C10 alkynyl group.

In one or more embodiments, the organometallic compound represented by Chemical Formula 1 may be selected from among compounds listed in Group 1.

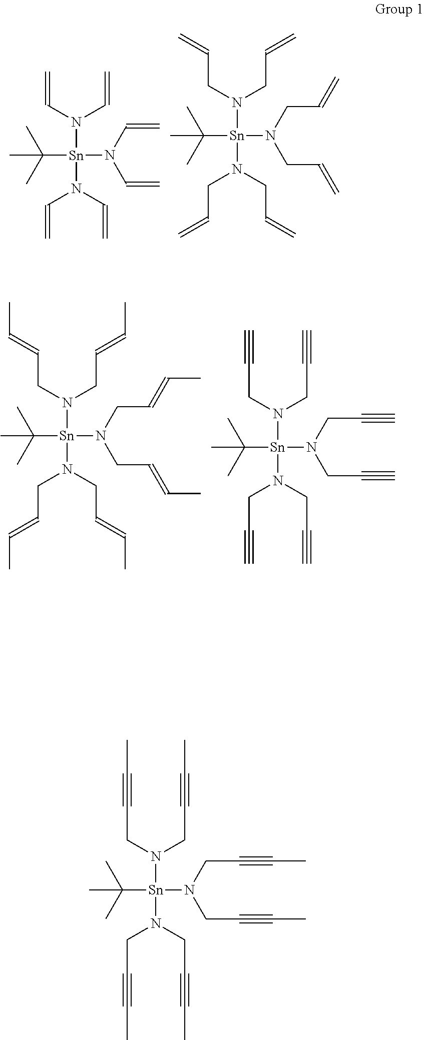

The organometallic compound represented by Chemical Formula 1 may strongly absorb extreme ultraviolet light at 13.5 nm and thus has excellent or suitable sensitivity to light with high energy.

In the semiconductor photoresist composition according to one or more embodiments, the organometallic compound represented by Chemical Formula 1 may be included in an amount of about 0.5 wt % to about 30 wt %, for example, about 1 wt % to about 30 wt %, for example, about 1 wt % to about 25 wt %, for example, about 1 wt % to about 20 wt %, for example, about 1 wt % to about 15 wt %, for example, about 1 wt % to about 10 wt %, for example, about 1 wt % to about 5 wt %, based on 100 wt % of a total weight of the semiconductor photoresist composition, but embodiments of the present disclosure are not limited thereto. If (e.g., when) the organometallic compound is included in the content (e.g., amount) within the above range, the storage stability and etch resistance of the semiconductor photoresist composition are improved, and the resolution characteristics are improved.

The semiconductor photoresist composition according to one or more embodiments may have excellent or suitable sensitivity and pattern-forming properties by including the aforementioned organometallic compound.

The solvent included in the semiconductor photoresist composition according to one or more embodiments may be an organic solvent, and may be, for example, an aromatic compound (e.g., xylene, toluene, and/or the like), an alcohol (e.g., 4-methyl-2-pentanol, 4-methyl-2-propanol, 1-butanol, methanol, isopropyl alcohol, 1-propanol), an ether (e.g., anisole, tetrahydrofuran), an ester (n-butyl acetate, propylene glycol monomethyl ether acetate, ethyl acetate, ethyl lactate), a ketone (e.g., methyl ethyl ketone, 2-heptanone), or a mixture thereof, but embodiments of the present disclosure are not limited thereto.

The semiconductor photoresist composition according to one or more embodiments may further include a resin in addition to the aforementioned organometallic compound and the solvent.

In one or more embodiments, the resin may be a phenol-based resin including at least one aromatic moiety selected from moieties listed in Group 2.

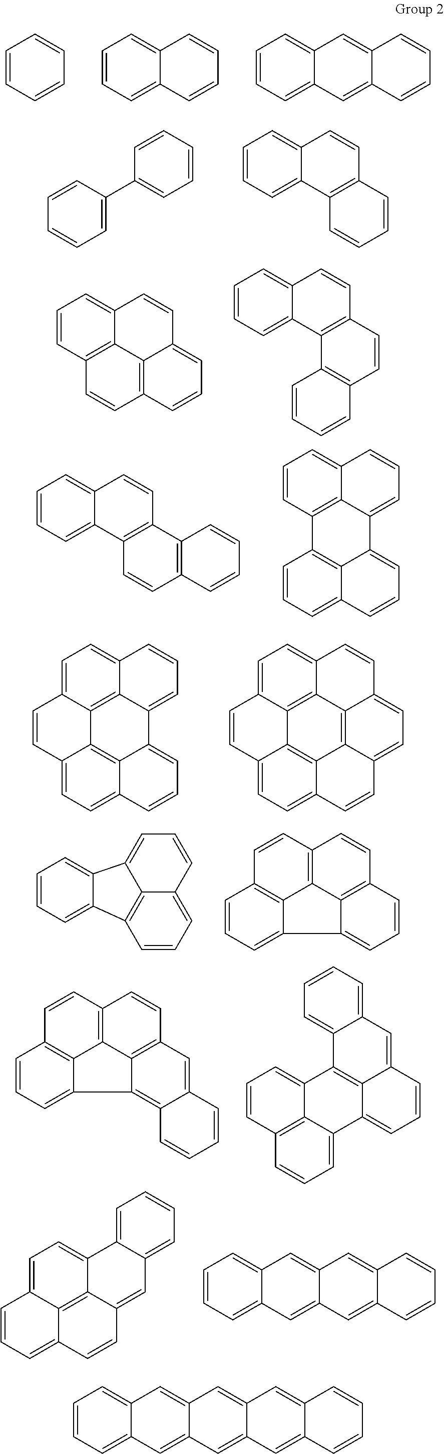

The resin may have a weight average molecular weight of about 500 to about 20,000.

The resin may be included in an amount of about 0.1 wt % to about 50 wt % based on a total weight of 100 wt % of the semiconductor photoresist composition.

If (e.g., when) the resin is included in the above content (e.g., amount) range, it may have excellent or suitable etch resistance and heat resistance.

In addition, the semiconductor photoresist composition according to one or more embodiments may be composed of the aforementioned organometallic compound, solvent, and resin. However, the semiconductor photoresist composition according to the aforementioned embodiments may further include one or more additives as needed. Non-limiting examples of the additives may be a surfactant, a crosslinking agent, a leveling agent, an organic acid, a quencher, or a combination thereof.

The surfactant may include, for example, an alkyl benzene sulfonate salt, an alkyl pyridinium salt, polyethylene glycol, a quaternary ammonium salt, or a combination thereof, but embodiments of the present disclosure are not limited thereto.

The crosslinking agent may be, for example, a melamine-based crosslinking agent, a substituted urea-based crosslinking agent, an acryl-based crosslinking agent, an epoxy-based crosslinking agent, or a polymer-based crosslinking agent, but embodiments of the present disclosure are not limited thereto. In one or more embodiments, it may be a crosslinking agent having at least two crosslinking forming substituents, for example, a compound such as methoxymethylated glycoluril, butoxymethylated glycoluril, methoxymethylated melamine, butoxymethylated melamine, methoxymethylated benzoguanamine, butoxymethylated benzoguanamine, 4-hydroxybutyl acrylate, acrylic acid, urethane acrylate, acryl methacrylate, 1,4-butanediol diglycidyl ether, glycidol, diglycidyl 1,2-cyclohexane dicarboxylate, trimethylpropane triglycidyl ether, 1,3-bis(glycidoxypropyl)tetramethyldisiloxane, methoxymethylated urea, butoxymethylated urea, methoxymethylated thiourea, and/or the like.

The leveling agent may be used for improving coating flatness during printing and may be a commercially available suitable leveling agent.

The organic acid may include p-toluenesulfonic acid, benzenesulfonic acid, p-dodecylbenzenesulfonic acid, 1,4-naphthalenedisulfonic acid, methanesulfonic acid, a fluorinated sulfonium salt, malonic acid, citric acid, propionic acid, methacrylic acid, oxalic acid, lactic acid, glycolic acid, succinic acid, or a combination thereof, but embodiments of the present disclosure are not limited thereto.

The quencher may be diphenyl (p-tolyl) amine, methyl diphenyl amine, triphenyl amine, phenylenediamine, naphthylamine, diaminonaphthalene, or a combination thereof.

An amount of the additives included in the semiconductor photoresist composition may be controlled or selected depending on desired or suitable properties.

In one or more embodiments, the semiconductor photoresist composition may further include a silane coupling agent as an adherence enhancer in order to improve a close-contacting force with the substrate (e.g., in order to improve adherence of the semiconductor photoresist composition to the substrate). The silane coupling agent may be, for example, a silane compound including a carbon-carbon unsaturated bond such as vinyltrimethoxysilane, vinyl triethoxysilane, vinyl trichlorosilane, vinyl tris(β-methoxyethoxy)silane; or 3-methacryloxypropyltrimethoxysilane, 3-acryloxypropyltrimethoxysilane, p-styryl trimethoxysilane, 3-methacryloxypropylmethyldimethoxysilane, or 3-methacryloxypropylmethyl diethoxysilane; trimethoxy[3-(phenylamino)propyl]silane, and/or the like, but embodiments of the present disclosure are not limited thereto.

The semiconductor photoresist composition may be formed into a pattern having a high aspect ratio without a collapse. Accordingly, in order to form a fine pattern having a width (e.g., line width) of, for example, about 5 nanometers (nm) to about 100 nm, for example, about 5 nm to about 80 nm, for example, about 5 nm to about 70 nm, for example, about 5 nm to about 50 nm, for example, about 5 nm to about 40 nm, for example, about 5 nm to about 30 nm, for example, about 5 nm to about 20 nm, or for example, about 5 nm to about 10 nm, the semiconductor photoresist composition may be used for a photoresist process using light in a wavelength in a range of about 5 nm to about 150 nm, for example, about 5 nm to about 100 nm, about 5 nm to about 80 nm, about 5 nm to about 50 nm, about 5 nm to about 30 nm, or about 5 nm to about 20 nm. Accordingly, the semiconductor photoresist composition according to one or more embodiments may be used to realize extreme ultraviolet lithography using an EUV light source of a wavelength of about 13.5 nm.

According to one or more embodiments, a method of forming patterns using the aforementioned semiconductor photoresist composition is provided. For example, the manufactured pattern may be a photoresist pattern.

A method of forming patterns according to one or more embodiments includes forming an etching-objective layer (e.g., etching-target layer) on a substrate, coating the semiconductor photoresist composition on the etching-objective layer to form a photoresist film, exposing and developing the photoresist film to form a photoresist film having a photoresist pattern formed thereon, and etching the etching-objective layer using the photoresist pattern as an etching mask.

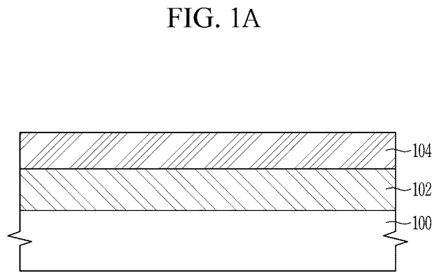

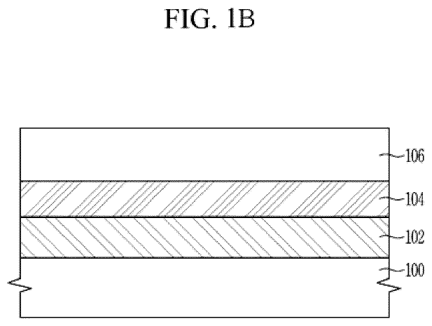

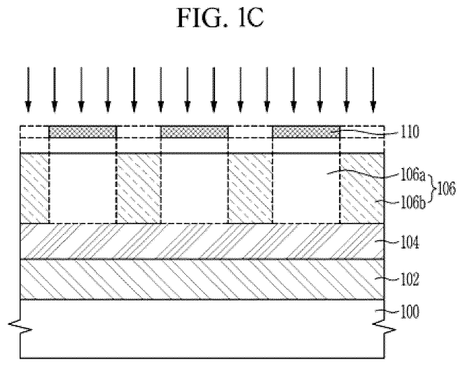

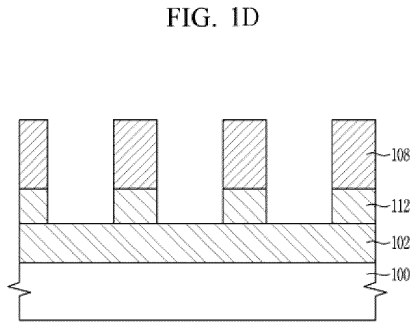

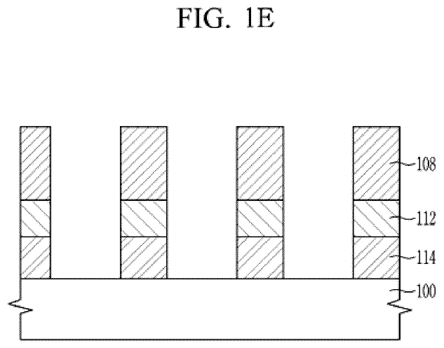

Hereinafter, a method of forming patterns using the semiconductor photoresist composition will be described in more detail by referring to FIGS. 1A-1E. FIGS. 1A-1E are cross-sectional views for illustrating a method of forming patterns using a semiconductor photoresist composition according to one or more embodiments.

Referring to FIG. 1A, an object for etching (e.g., etching-objective layer or etching-target layer) is prepared. The object for etching may be a thin film 102 formed on a semiconductor substrate 100. Hereinafter, the object for etching is limited to the thin film 102. A surface of the thin film 102 is washed to remove impurities and/or the like remaining thereon. The thin film 102 may be, for example, a silicon nitride layer, a polysilicon layer, or a silicon oxide layer.

Subsequently, a resist underlayer composition for forming a resist underlayer 104 is spin-coated on the surface of the washed thin film 102. However, embodiments of the present disclosure are not limited thereto, and various suitable coating methods, for example, a spray coating, a dip coating, a knife edge coating, a printing method (for example an inkjet printing and/or a screen printing), and/or the like may be used.

In one or more embodiments, the coating process of the resist underlayer may not be provided, but hereinafter, a process including a coating of the resist underlayer is described.

Then, the coated resist underlayer composition is dried and baked to form the resist underlayer 104 on the thin film 102. The baking may be performed at about 100° C. to about 500° C., for example, about 100° C. to about 300° C.

The resist underlayer 104 is formed between the substrate 100 and a photoresist film 106 and thus may prevent or reduce non-uniformity of pattern formability of a photoresist line width if (e.g., when) a ray reflected from on the interface between the substrate 100 and the photoresist film 106 or a hardmask between layers is scattered into an unintended photoresist region.

Referring to FIG. 1B, the photoresist film 106 is formed by coating the semiconductor photoresist composition on the resist underlayer 104. The photoresist film 106 is obtained by coating the aforementioned semiconductor photoresist composition on the thin film 102 formed on the substrate 100 and then, curing it through a heat treatment.

In one or more embodiments, the formation of a pattern by using the semiconductor photoresist composition may include coating the semiconductor photoresist composition on the substrate 100 having the thin film 102 through spin coating, slit coating, inkjet printing, and/or the like and then, drying it to form the photoresist film 106.

The semiconductor photoresist composition has already been illustrated in more detail and will not be illustrated again.

Subsequently, the substrate 100 having the photoresist film 106 is subjected to a first baking process. The first baking process may be performed at about 80° C. to about 120° C.

Referring to FIG. 1C, the photoresist film 106 may be selectively exposed using a patterned mask 110.

For example, the exposure may use an activation radiation with light having a high energy wavelength such as EUV (extreme ultraviolet; a wavelength of about 13.5 nm), an E-Beam (an electron beam), and/or the like as well as light having a short wavelength such as an i-line (a wavelength of about 365 nm), a KrF excimer laser (a wavelength of about 248 nm), an ArF excimer laser (a wavelength of about 193 nm), and/or the like.

In one or more embodiments, light or exposure beam for the exposure according to one or more embodiments may be light having a short wavelength in a range of about 5 nm to about 150 nm and/or a high energy wavelength, for example, EUV (extreme ultraviolet; a wavelength of 13.5 nm), and/or may be an E-Beam (an electron beam), and/or the like.

The exposed region 106b of the photoresist film 106 has a different solubility from the unexposed region 106a of the photoresist film 106 by forming a polymer by a crosslinking reaction such as condensation between organometallic compounds.

Subsequently, the substrate 100 is subjected to a second baking process. The second baking process may be performed at a temperature of about 90° C. to about 200° C. The exposed region 106b of the photoresist film 106 becomes indissoluble regarding a developer due to the second baking process.

In FIG. 1D, the unexposed region 106a of the photoresist film is dissolved and removed using the developer to form a photoresist pattern 108. For example, the unexposed region 106a of the photoresist film is dissolved and removed by using an organic solvent such as 2-heptanone and/or the like to complete the photoresist pattern 108 corresponding to a negative tone image.

As described above, a developer used in a method of forming patterns according to one or more embodiments may be an organic solvent. The organic solvent used in the method of forming patterns according to one or more embodiments may be, for example, a ketone such as methylethylketone, acetone, cyclohexanone, 2-heptanone, and/or the like, an alcohol such as 4-methyl-2-propanol, 1-butanol, isopropanol, 1-propanol, methanol, and/or the like, an ester such as propylene glycol monomethyl ether acetate, ethyl acetate, ethyl lactate, n-butyl acetate, butyrolactone, and/or the like, an aromatic compound such as benzene, xylene, toluene, and/or the like, or a combination thereof.

However, the photoresist pattern according to one or more embodiments is not necessarily limited to the negative tone image but may be formed to have a positive tone image. Here, a developer used for forming the positive tone image may be a quaternary ammonium hydroxide composition such as tetraethylammonium hydroxide, tetrapropylammonium hydroxide, tetrabutylammonium hydroxide, or a combination thereof.

As described above, exposure to light having a high energy such as EUV (extreme ultraViolet; a wavelength of 13.5 nm), to an E-Beam (an electron beam), and/or the like and/or to light such as i-line (wavelength of about 365 nm), KrF excimer laser (wavelength of about 248 nm), ArF excimer laser (wavelength of about 193 nm), and/or the like may provide a photoresist pattern 108 having a width of a thickness of about 5 nm to about 100 nm. For example, in one or more embodiments, the photoresist pattern 108 may have a width of a thickness of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, about 5 nm to about 20 nm, or about 5 nm to about 10 nm.

In one or more embodiments, the photoresist pattern 108 may have a pitch (center-to-center distance between adjacent features in the pattern) having (with) a half-pitch of less than or equal to about 50 nm, for example less than or equal to about 40 nm, for example less than or equal to about 30 nm, for example less than or equal to about 20 nm, or for example less than or equal to about 10 nm, and a line width roughness of less than or equal to about 10 nm, or less than or equal to about 5 nm, less than or equal to about 3 nm, less than or equal to about 2 nm, or less than or equal to about 1 nm.

According to one or more embodiments, a photoresist film manufactured by the aforementioned method of forming patterns may be provided.

Subsequently, the resist underlayer 104 is etched using the photoresist pattern 108 formed on the photoresist film as an etching mask. Through this etching process, an organic film pattern 112 is formed. The organic film pattern 112 also may have a width corresponding to that of the photoresist pattern 108.

Referring to FIG. 1E, the exposed thin film 102 is etched by applying the photoresist pattern 108 as an etching mask. As a result, the thin film is formed as a thin film pattern 114.

The etching of the thin film 102 may be, for example, dry etching using an etching gas, and the etching gas may be, for example, CHF₃, CF₄, Cl₂, BCl₃ or a mixed gas thereof.

In the exposure process, the thin film pattern 114 formed by using the photoresist pattern 108 formed through the exposure process performed by using an EUV light source may have a width corresponding to that of the photoresist pattern 108. For example, in one or more embodiments, the thin film pattern 114 may have a width (e.g., line width) of about 5 nm to about 100 nm which is equal to that of the photoresist pattern 108. For example, in one or more embodiments, the thin film pattern 114 formed by using the photoresist pattern 108 formed through the exposure process performed by using an EUV light source may have a width (e.g., line width) of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm, for example, a width (e.g., line width) of less than or equal to about 20 nm, like that of the photoresist pattern 108.

Hereinafter, the present disclosure will be described in more detail through examples of the preparation of the aforementioned semiconductor photoresist composition. However, the present disclosure is technically not restricted by the following examples.

### Synthesis of Organometallic Compounds

### Synthesis Example 1

t-butylSnPh₃ (40.7 g) and vinylamine (34.4 g) were added in a 100 mL round-bottom flask and heated under reflux for 24 hours. Unreacted substances were removed under reduced pressure to obtain a compound represented by Chemical Formula 2.

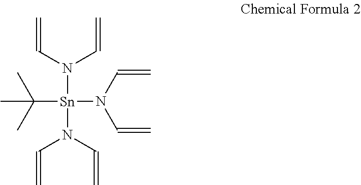 [SMILES: C=C[N](C=C)[Sn]([N](C=C)C=C)([N](C=C)C=C)[C](C)(C)C]

### Synthesis Example 2

A compound represented by Chemical Formula 3 was obtained by performing substantially the same procedure as in Synthesis Example 1 except that allylamine (45.7 g) was used instead of vinylamine.

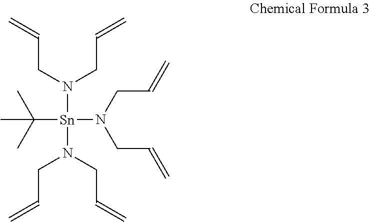 [SMILES: C=CC[N](CC=C)[Sn]([N](CC=C)CC=C)([N](CC=C)CC=C)[C](C)(C)C]

### Synthesis Example 3

A compound represented by Chemical Formula 4 was obtained by performing substantially the same procedure as in Synthesis Example 1, except that propargylamine (44.1 g) was used instead of vinylamine.

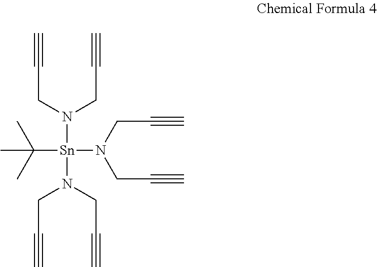 [SMILES: C#CC[N](CC#C)[Sn]([N](CC#C)CC#C)([N](CC#C)CC#C)[C](C)(C)C]

### Synthesis Example 4

A compound represented by Chemical Formula 5 was obtained by performing substantially the same procedure as in Synthesis Example 1, except that 3-butyn-1-amine (56.1 g) was used instead of vinylamine.

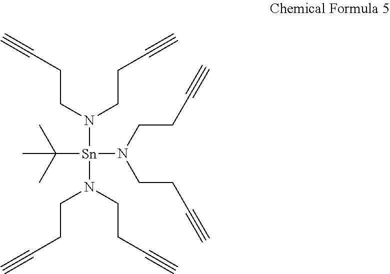 [SMILES: C#CCC[N](CCC#C)[Sn]([N](CCC#C)CCC#C)([N](CCC#C)CCC#C)[C](C)(C)C]

### Synthesis Example 5

A compound represented by Chemical Formula 6 was obtained by performing substantially the same procedure as in Synthesis Example 1, except that 2-Buten-1-amine (100 g) was used instead of vinylamine.

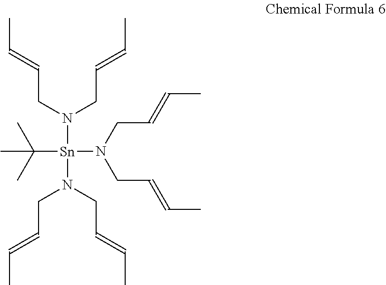 [SMILES: C/C=C/C[N](C/C=C/C)[Sn]([N](C/C=C/C)C/C=C/C)([N](C/C=C/C)C/C=C/C)[C](C)(C)C]

### Synthesis Example 6

A compound represented by Chemical Formula 7 was obtained by performing substantially the same procedure as in Synthesis Example 1, except that 2-Butyn-1-amine (100 g) was used instead of vinylamine.

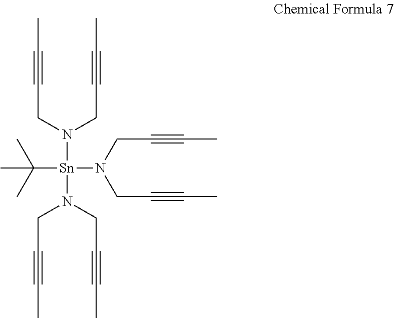 [SMILES: CC#CC[N](CC#CC)[Sn]([N](CC#CC)CC#CC)([N](CC#CC)CC#CC)[C](C)(C)C]

### Comparative Synthesis Example 1

A compound represented by Chemical Formula 8 was obtained by performing substantially the same procedure as in Synthesis Example 1 except that propylamine (47.3 g) was used instead of vinylamine.

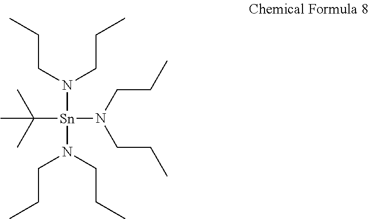 [SMILES: CCC[N](CCC)[Sn]([N](CCC)CCC)([N](CCC)CCC)[C](C)(C)C]

### Preparation of Semiconductor Photoresist Compositions

### Examples 1 to 6 and Comparative Example 1

The organometallic compounds obtained in Synthetic Examples 1 to 6 and Comparative Synthetic Example 1 were each dissolved at a concentration of 3 wt % in PGMEA (propylene glycol monomethyl ether acetate) and filtered through a 0.1 μm PTFE syringe filter to prepare each respective photoresist composition.

### Evaluation 1: Evaluation of Sensitivity and Line Edge Roughness (LER)

Each of the photoresist compositions according to Examples and Comparative Examples was spin-coated for 30 seconds at 1500 rpm on a 200 mm circular silicon wafer whose surface was deposited with hexamethyldisilazane (HMDS), and baked at 110° C. for 60 seconds. After application, it was baked (post-apply bake, PAB) and then left at room temperature (23±2° C.) for 30 seconds, to prepare a respective coated wafer.

Then, a linear array of 50 circular pads with a diameter of 500 μm was projected onto the wafer coated with the photoresist composition using EUV light (Lawrence Berkeley National Laboratory Micro Exposure Tool, MET). Here, pad exposure time was adjusted to ensure that the EUV light in an increased dose was applied to each pad.

Then, the photoresist and the substrate were baked at 160° C. for 120 seconds on a hot plate after the exposure. The baked film was developed in a PGMEA solvent to form a negative tone image. Finally, the obtained film was baked again at 150° C. for 2 minutes on the hot plate, completing the process.

The remaining resist thickness of the exposed pad was measured using an ellipsometer. The remaining thickness was measured for each exposure dose and then, graphed as a function to the exposure doses to measure sensitivity, and LER was measured from an FE-SEM (Field Emission Scanning Electron Microscopy) image to evaluate line edge roughness, and then, the results are shown in Table 1.

### Evaluation 2: Evaluation of Defects

On a 12-inch silicon substrate, a lower SiON film/a spin-on carbon film/an upper SiON film in order were formed. On the upper SiON film, each of the photoresist compositions according to the examples and the comparative examples was used to form a 1:1 line/space photoresist pattern with a pitch of 36 nm in an EUV lithography method. The photoresist pattern was transferred to the lower SiON film through dry etching using a plasma. Then, all defects including bridge defects between the line patterns were inspected in a bright field with a defect analysis equipment using a DUV (deep ultraviolet) laser. The inspected defects were classified by using SEM (scanning electron microscopy) and then, shown as the number of the classified defects per unit area (ea/cm²).

Herein, if (e.g., when) the number of SLO (single line openings) defects in the case of not applying any of the photoresist compositions of the present disclosure was converted to 100, if the number of defects was less than or equal to 80%, ‘∘’ was given, and if the number of defects was greater than 80%, ‘X’ was given.

TABLE 1

| | Organometallic | LER | Sensitivity | Defect |
|---|---|---|---|---|
| | compound | (nm) | (mJ/cm²) | evaluation |
| Example 1 | Chemical | 3.0 | 34.8 | ∘ |
| | Formula 2 | | | |
| Example 2 | Chemical | 3.2 | 35.5 | ∘ |
| | Formula 3 | | | |
| Example 3 | Chemical | 3.1 | 31.4 | ∘ |
| | Formula 4 | | | |
| Example 4 | Chemical | 2.9 | 30.8 | ∘ |
| | Formula 5 | | | |
| Example 5 | Chemical | 2.8 | 31.5 | ∘ |
| | Formula 6 | | | |
| Example 6 | Chemical | 2.8 | 30.4 | ∘ |
| | Formula 7 | | | |
| Comparative | Chemical | 4.1 | 53.7 | x |
| Example 1 | Formula 8 | | | |

From the results in Table 1, it should be evident that the semiconductor photoresist compositions prepared utilizing the organometallic compounds of Examples 1 to 6—each incorporating a nitrogen-containing unsaturated amine ligand—exhibited improved performance compared to the composition of Comparative Example 1, which utilized a saturated alkylamine ligand. For example, the compositions of Examples 1 to 6 demonstrated lower line edge roughness (LER), higher sensitivity (i.e., lower required exposure dose), and superior defect suppression, particularly with respect to bridge defects. These improvements are for enabling high-resolution patterning at, e.g., sub-36 nm pitches in EUV lithography processes.

The enhanced performance is attributed to the structural features of the organometallic compounds synthesized in Synthesis Examples 1 to 6. The presence of unsaturated functional groups (e.g., vinyl, allyl, propargyl, and butynyl) in the amine ligands is believed to facilitate more efficient crosslinking and energy absorption during EUV exposure, leading to improved pattern fidelity and reduced stochastic variation. Additionally, the nitrogen-containing ligands may contribute to better film uniformity and developer resistance, further supporting the formation of defect-free patterns. In contrast, the compound of Comparative Example 1, which lacks such unsaturated functionalities, exhibited inferior sensitivity and LER, and a higher incidence of pattern defects. These findings show the importance of ligand design in tuning the performance of organometallic photoresists for next-generation semiconductor manufacturing.

As utilized herein, the terms “and/or” and “or” may include any and all combinations of one or more of the associated listed items. The “/” utilized below may be interpreted as “and” or as “or” depending on the situation. In the present disclosure, expressions such as “at least one of,” “one of,” and “selected from,” when preceding a list of elements, modify the entire list of elements and do not modify the individual elements of the list. For example, “at least one of a, b or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof.

It will be further understood that the terms “comprise(s)/comprising”, “include(s)/including,” or “have/has/having,” when utilized in the present disclosure, specify the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having,” or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As utilized herein, the singular forms “a,” “an,” and “the” are intended to include the plural forms as well, unless the context clearly indicates otherwise. Further, the utilization of “may” when describing embodiments of the present disclosure refers to “one or more embodiments of the present disclosure”.

In the context of the present disclosure and unless otherwise defined, the terms “use,” “using,” and “used” may be considered synonymous with the terms “utilize,” “utilizing,” and “utilized,” respectively.

As utilized herein, the term “about,” or similar terms are used as terms of approximation and not as terms of degree, and are intended to account for the inherent deviations in measured or calculated values that would be recognized by those of ordinary skill in the art. “About” or “approximately,” as used herein, is also inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

A pattern forming device, a semiconductor forming device and/or any other relevant devices or components according to embodiments of the present invention described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

Hereinbefore, the certain example embodiments have been described and illustrated, however, it is apparent to a person with ordinary skill in the art that the present disclosure is not limited to the embodiment as described, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the claims of the present disclosure. It is further to be understood that the scope of the present disclosure is defined by the appended claims and equivalents thereof rather than the detailed description described above, and all modifications and alterations derived from the claims and their equivalents fall within the scope of the present disclosure.

Reference Numerals

| | |
|---|---|
| 100: substrate | 102: thin film |
| 104: resist underlayer | 106: photoresist film |
| 106a: unexposed region | 106b: exposed region |
| 108: photoresist pattern | 112: organic film pattern |
| 110: patterned mask | 114: thin film pattern |

What is claimed is:

1. A semiconductor photoresist composition, comprising:
an organometallic compound represented by Chemical Formula 1; and
a solvent: 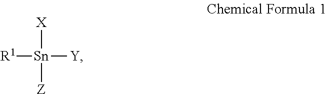
wherein, in Chemical Formula 1,
R¹ is selected from among a substituted or unsubstituted C1 to C20 alkyl group, a substituted or unsubstituted C2 to C30 heteroalkyl group, a substituted or unsubstituted C3 to C20 cycloalkyl group, a substituted or unsubstituted C2 to C30 heterocycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C2 to C30 heteroaryl group, a substituted or unsubstituted C7 to C30 arylalkyl group, a substituted or unsubstituted C4 to C30 heteroarylalkyl group, and a substituted or unsubstituted C1 to C30 alkylcarbonyl group,
X, Y, and Z are each independently a substituted or unsubstituted C1 to C20 alkyl group, a substituted or unsubstituted C2 to C30 heteroalkyl group, a substituted or unsubstituted C3 to C20 cycloalkyl group, a substituted or unsubstituted C2 to C30 heterocycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C2 to C30 heteroaryl group, a substituted or unsubstituted C7 to C30 arylalkyl group, a substituted or unsubstituted C4 to C30 heteroarylalkyl group, a substituted or unsubstituted C1 to C30 alkylcarbonyl group, or —N(L^{a}-R^{a})(L^{b}-R^{b}),
at least one selected from among X, Y, and Z is —N(L^{a}-R^{a})(L^{b}-R^{b}),
L^{a} and L^{b} are each independently a single bond or a substituted or unsubstituted C1 to C10 alkylene group, and
R^{a} and R^{b} are each independently a substituted or unsubstituted C2 to C20 alkenyl group, a substituted or unsubstituted C2 to C20 alkynyl group.

2. The semiconductor photoresist composition as claimed in claim 1, wherein
L^{a} and L^{b} are each independently a single bond or a substituted or unsubstituted C1 to C10 alkylene group,
R^{a} and R^{b} are each independently —C(R²)═C(R³)(R⁴) or —C≡C(R⁵),
R² to R⁴ are each independently hydrogen, a substituted or unsubstituted C1 to C20 alkyl group, a substituted or unsubstituted C3 to C20 cycloalkyl group, a substituted or unsubstituted C6 to C30 aryl group, -L¹-C(R⁶)═C(R⁷)(R⁸), or -L²-C≡C(R⁹),
at least one of R³ and R⁴ is a substituted or unsubstituted C1 to C20 alkyl group, a substituted or unsubstituted C3 to C20 cycloalkyl group, a substituted or unsubstituted C6 to C30 aryl group, -L¹-C(R⁶)═C(R⁷)(R⁸), or -L²-C≡C(R⁹),
R⁵ is a substituted or unsubstituted C1 to C20 alkyl group, a substituted or unsubstituted C3 to C20 cycloalkyl group, a substituted or unsubstituted C6 to C30 aryl group, -L¹-C(R⁶)═C(R⁷)(R⁸), or -L²-C≡C(R⁹),
L¹ and L² are each independently a substituted or unsubstituted C1 to C10 alkylene group, and
R⁶ to R⁹ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, or a substituted or unsubstituted C6 to C30 aryl group.

3. The semiconductor photoresist composition as claimed in claim 1, wherein
X, Y, and Z are each independently —N(L^{a}-R^{a})(L^{b}-R^{b}).

4. The semiconductor photoresist composition as claimed in claim 3, wherein
X, Y, and Z are the same as one another.

5. The semiconductor photoresist composition as claimed in claim 1, wherein
R¹ is selected from among a substituted or unsubstituted C1 to C10 alkyl group, a substituted or unsubstituted C2 to C20 heteroalkyl group, a substituted or unsubstituted C3 to C12 cycloalkyl group, a substituted or unsubstituted C2 to C20 heterocycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C2 to C20 heteroaryl group, a substituted or unsubstituted C7 to C20 arylalkyl group, a substituted or unsubstituted C4 to C20 heteroarylalkyl group, and a substituted or unsubstituted C1 to C20 alkylcarbonyl group.

6. The semiconductor photoresist composition as claimed in claim 1, wherein
R¹ is a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted tert-pentyl group, a substituted or unsubstituted 1-methylpropyl group, a substituted or unsubstituted 1,1-dimethylpropyl group, a substituted or unsubstituted 2,2-dimethylpropyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted phenyl group, a substituted or unsubstituted tolyl group, a substituted or unsubstituted xylene group, a substituted or unsubstituted benzyl group, or a combination thereof.

7. The semiconductor photoresist composition as claimed in claim 1, wherein
R² to R⁴ are each independently hydrogen, a substituted or unsubstituted C1 to C10 alkyl group, a substituted or unsubstituted C3 to C10 cycloalkyl group, a substituted or unsubstituted C6 to C20 aryl group, -L¹-C(R⁶)═C(R⁷)(R⁸), or -L²-C≡C(R⁹),
at least one of R³ or R⁴ is a substituted or unsubstituted C1 to C10 alkyl group, a substituted or unsubstituted C3 to C10 cycloalkyl group, a substituted or unsubstituted C6 to C20 aryl group, -L¹-C(R⁶)═C(R⁷)(R⁸), or -L²-C≡C(R⁹),
R⁵ is a substituted or unsubstituted C1 to C10 alkyl group, a substituted or unsubstituted C3 to C10 cycloalkyl group, a substituted or unsubstituted C6 to C20 aryl group, -L¹-C(R⁶)═C(R⁷)(R⁸), or -L²-C≡C(R⁹),
L¹ and L² are each independently a substituted or unsubstituted C1 to C6 alkylene group, and
R⁶ to R⁹ are each independently hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, or a substituted or unsubstituted C6 to C20 aryl group.

8. The semiconductor photoresist composition as claimed in claim 1, wherein
R² to R⁴ are each independently hydrogen, a substituted or unsubstituted C1 to C10 alkyl group, -L¹-C(R⁶)═C(R⁷)(R⁸), or -L²-C≡C(R⁹),
at least one of R³ or R⁴ is a substituted or unsubstituted C1 to C10 alkyl group, -L¹-C(R⁶)═C(R⁷)(R⁸), or -L²-C≡C(R⁹),
R⁵ is a substituted or unsubstituted C1 to C10 alkyl group, -L¹-C(R⁶)═C(R⁷)(R⁸), or -L²-C≡C(R⁹),
L¹ and L² are each independently a substituted or unsubstituted C1 to C6 alkylene group, and
R⁶ to R⁹ are each independently hydrogen, a substituted or unsubstituted C1 to C10 alkyl group, a substituted or unsubstituted C2 to C10 alkenyl group, or a substituted or unsubstituted C2 to C10 alkynyl group.

9. The semiconductor photoresist composition as claimed in claim 1, wherein
the organometallic compound represented by Chemical Formula 1 is selected from among compounds listed in Group 1:

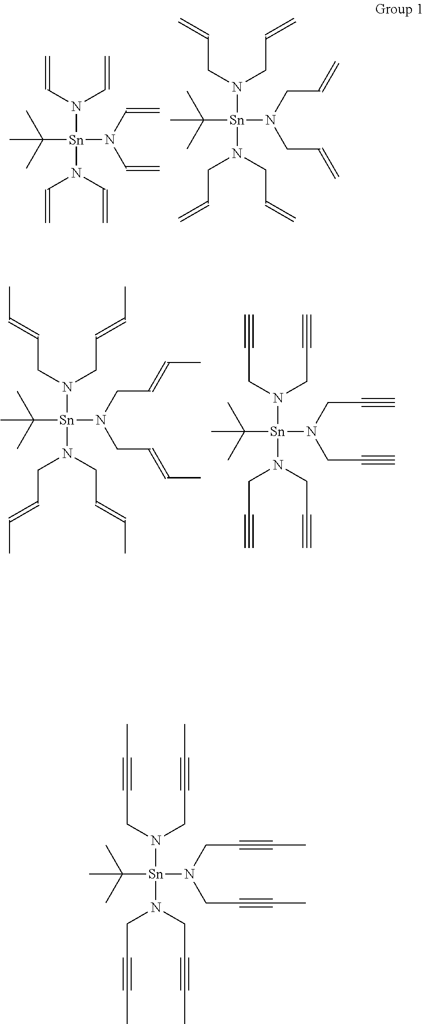

10. The semiconductor photoresist composition as claimed in claim 1, wherein
the organometallic compound represented by Chemical Formula 1 is in an amount of about 0.5 wt % to about 30 wt % based on a total weight of 100 wt % of the semiconductor photoresist composition.

11. The semiconductor photoresist composition as claimed in claim 1, wherein
the semiconductor photoresist composition further comprises one or more additives selected from among a surfactant, a crosslinking agent, a leveling agent, an organic acid, a quencher, and a combination thereof.

12. A method, comprising
forming an etching-objective layer on a substrate;
coating the semiconductor photoresist composition of claim 1 on the etching-objective layer to form a photoresist film;
exposing and developing the photoresist film to form a photoresist film having a photoresist pattern formed thereon; and
etching the etching-objective layer utilizing the photoresist pattern as an etching mask,
wherein the method is a method of forming patterns.

13. The method as claimed in claim 12, wherein
the forming of the photoresist pattern is performed utilizing light with a wavelength of about 5 nm to about 150 nm.

14. The method as claimed in claim 12, wherein
the photoresist pattern has a width of about 5 nm to about 100 nm.
